(19) United States
(12) Patent Application Publication
(10) Pub. No.: US 2006/0220670 A1
(43) Pub. Date: Oct. 5, 2006

(54) Method for measuring cell gap variation of liquid crystal panel and apparatus thereof

(75) Inventors: Tai-Chi Huang, Gueishan Township (TW); Chih-Liang Liao, Gueishan Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Display Inc.

(21) Appl. No.: 11/368,574

(22) Filed: Mar. 6, 2006

(30) Foreign Application Priority Data
Mar. 8, 2005 (TW) 94106954

(51) Int. Cl. G01R 31/00; G01B 11/06; G01J 4/00

(52) U.S. Cl. 324/770; 356/632; 356/364

(57) ABSTRACT

A method for measuring a cell gap of a liquid crystal panel, comprises providing a detection device, holding the liquid crystal panel vertically, heating the liquid crystal panel to a detection temperature between 50° C. to 70° C., and measuring the cell gap of the liquid crystal panel with the detection device.

### BACKGROUND

The invention relates to a detection method and apparatus for performing same, and more particularly to a method for measuring a cell gap of a liquid crystal panel.

A liquid crystal display utilizes liquid crystal controlling brightness and color. In the liquid crystal display manufacturing process, liquid crystal is injected or dripped between two parallel glass substrates. Typically, after liquid crystal is inserted between the glass substrates, as shown in FIG. 1a, liquid crystal panel 2(comprising liquid crystal and glass substrates) is placed on a stage 3 for inspecting a cell gap by a detection device 1. The detection device 1 emits a light beam 11 toward liquid crystal panel 2 and receives a light beam 12 reflected therefrom. The detection device 1 measures the cell gap of liquid crystal panel 2 utilizing the formula:
R=(nx−ny)×(cell gap) (1)

“R” is phase retardation between light beam 11 and light beam 12, and “nx−ny” is birefringence of liquid crystal.

Liquid crystal size, however, increases with increased liquid crystal panel size. Thus, when the liquid crystal panel is held vertically (for example, placed on a table or a wall), liquid crystal flows downward due to gravity. FIG. 1b shows an inner structure of liquid crystal panel 2. When liquid crystal panel 2 is held vertically, liquid crystal 22 between the glass substrates 21 flows downward in the direction indicated by the arrows. Thus, the cell gap uniformity decreases (for example, the cell gap increases in lower area of liquid crystal panel 2) resulting in decreased quality and life of liquid crystal panel.

Conventional detection methods detect a horizontally placed liquid crystal panel, which cannot detect a non-uniform cell gap as the force of gravity does not act on the horizontally placed LCD panel.

As well, when liquid crystal display displays, a backlight module heats the liquid crystal panel. Thus, liquid crystal expands and the cell gap uniformity further decreases. In conventional detection methods, the liquid crystal panel is not exposed to heat. Thus, non-uniform cell gap due to heat expansion cannot be detected.

### SUMMARY

A method for measuring a cell gap of a liquid crystal panel comprises providing a detection device, holding the liquid crystal panel vertically, heating the liquid crystal panel to a detection temperature between 50° C. to 70° C., and measuring the cell gap of the liquid crystal panel with the detection device.

The apparatus of the invention detects the vertically-held liquid crystal panel to detect cell gap non-uniformity due to the force of gravity. The apparatus of the invention also heats the liquid crystal panel to between 50° C. to 70° C. to detect cell gap non-uniformity due to heat expansion. Thus, the method of the invention increases life and reliability of the liquid crystal panel.

### BRIEF DESCRIPTION OF THE DRAWINGS

The invention will be more fully understood from the following detailed description and the accompanying drawings, given by the way of illustration only and thus not intended to limit the disclosure.

FIG. 1a shows a conventional method for measuring cell gap of a liquid crystal panel;

FIG. 1b shows liquid crystal flowing downward due to the force of gravity;

FIG. 2a shows a holder of a detection apparatus of the invention in a vertical orientation;

FIG. 2b shows the holder of the detection apparatus of the invention in a horizontal orientation;

FIG. 3 shows the area of the liquid crystal panel to be detected.

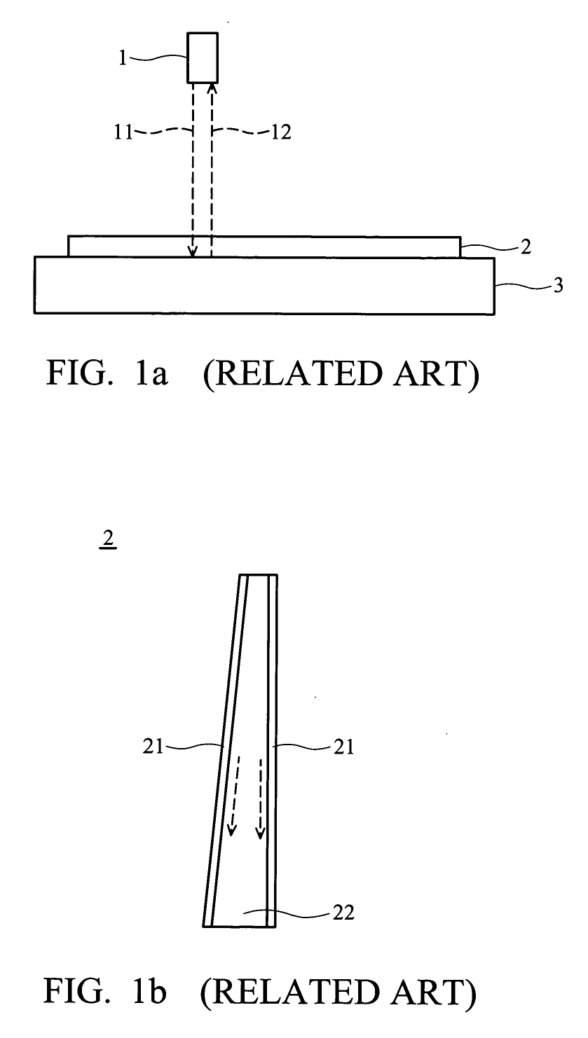

### DETAILED DESCRIPTION

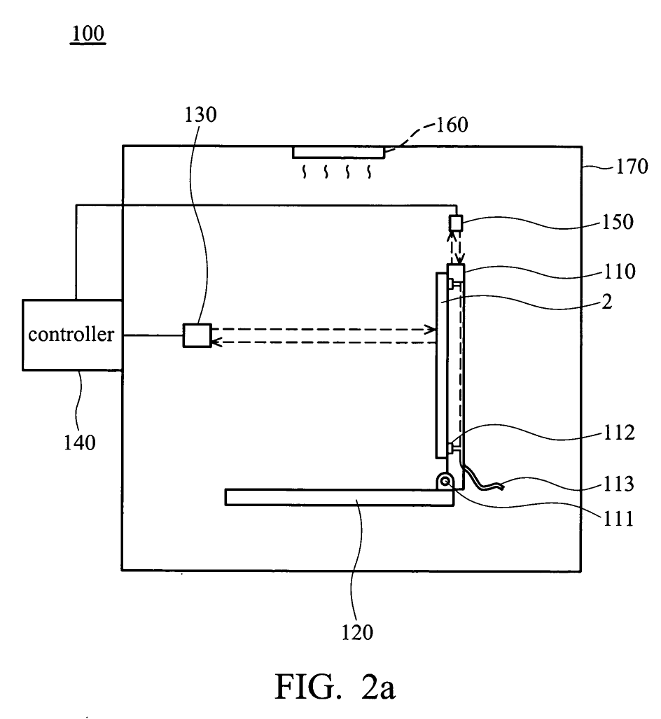

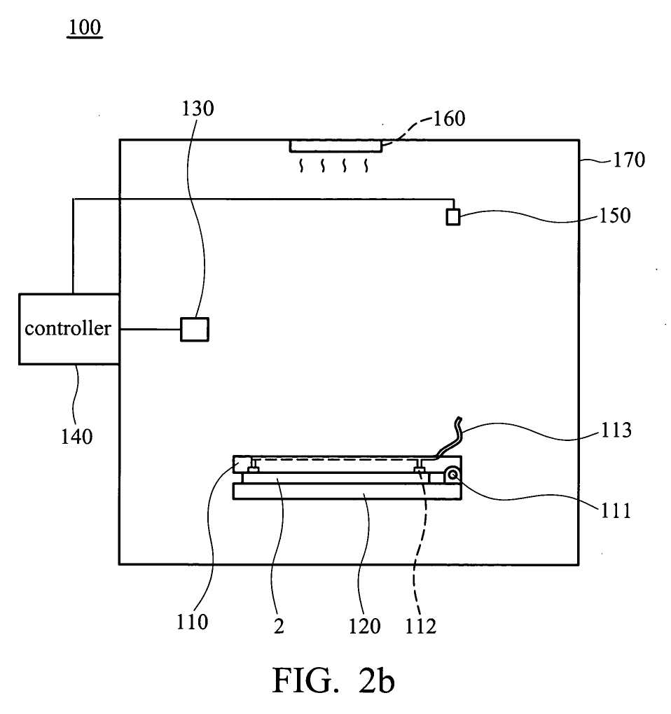

FIG. 2a shows a detection apparatus 100 for measuring a liquid crystal panel 2. The detection apparatus 100 comprises a holder 110, a stage 120, a detection device 130, a controller 140, a positioning element 150, a heater 160 and a chamber 170. The holder 110, stage 120, detection device 130, positioning element 150 and the heater 160 are disposed in the chamber 170. The holder 110 pivots on a pivot element 111 disposed on the stage 120. The holder 110 comprises a plurality of vacuum elements 112 (vacuum openings) disposed on a surface of the holder 110. The vacuum elements 112 are connected to a vacuum pipe 113 and draw the liquid crystal panel 2 with vacuum force. The holder 110 can also hold the liquid crystal panel 2 by abutting, bolting or other means.

The holder 110 holds the liquid crystal panel 2 in a vertical orientation (as shown in FIG. 2a). The positioning element 150 detects the position of the holder 110 to ensure that the holder 110 is in the vertical orientation. The detection device 130 measures the cell gap of the vertically-oriented liquid crystal panel 2. The detection device 130 and the positioning element 150 are coupled to the controller 140, and measurement results thereof are transmitted to the controller 140 and output therethrough. As well, a user controls the detection device 130 via the controller 140.

The positioning element 150 is an optical sensor, pressure sensor or other sensors. The detection device 130 measures the cell gap according to formula (1), such as an optical detection device provided by OTSUKA. The controller 140 is a computer, and controls the sensitivity of the detection device 130 to precisely detect a liquid crystal panel 2 with various types and sizes. The liquid crystal panel 2 is a reflective, transmissive or reflective-transmissive liquid crystal panel.

The heater 160 heats the liquid crystal panel 2 to a detection temperature between 50° C. to 70° C., preferably 60° C. In the invention, the heater 160 is disposed on an inner wall of the chamber 170 and heats the liquid crystal panel 2 via radiation or conduction. The heater 160 can also be disposed on the holder 110 and heats the liquid crystal panel 2 via conduction.

The detection method of the invention is described hereafter.

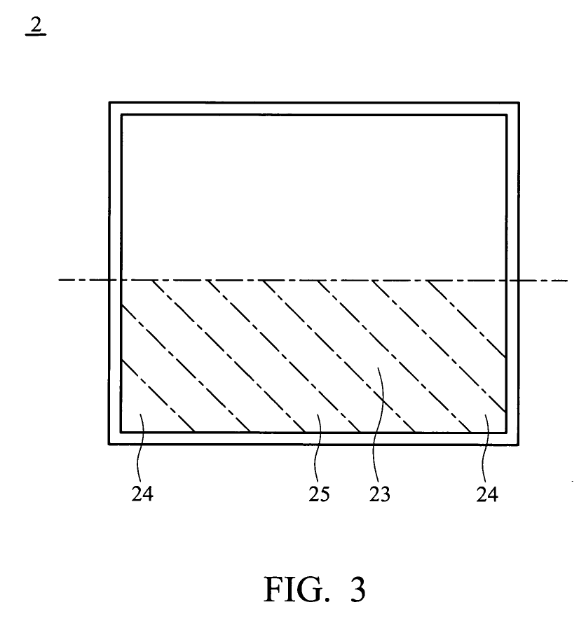

With reference to FIG. 2b, before detection, the liquid crystal panel 2 is transmitted to a predetermined position on the stage. The holder 110 then holds the liquid crystal panel 2 via the vacuum elements 112 in a horizontal orientation. Next, as shown in FIG. 2a, the holder 110 pivots and rotates the liquid crystal panel 2 to the vertical orientation. When the holder 110 arrives the vertical orientation, the positioning element 150 sends a positioning signal to the controller 140. The controller 140 activates the detection device 130 after receiving the positioning signal. The detection device 130 continuously monitors the liquid crystal panel 2 which is kept at a detection temperature between 50° C. to 70° C. for 3 hours to measure a variation of the cell gap thereof. With reference to FIG. 3, the detection device 130 detects a lower area 23 of the liquid crystal panel 2, preferably lower corner area 24 or a lower edge area 25. After detection, the holder 110 rotates the liquid crystal panel 2 to the horizontal orientation and releases the liquid crystal panel 2.

The detection method and apparatus of the invention can be utilized in a high temperature ageing test to monitor the vertically-oriented liquid crystal panel. The heater 160 and the chamber 170 can be replaced by heating apparatus of the high temperature ageing test, and the detection temperature is a predetermined temperature thereof.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method for measuring a cell gap of a liquid crystal panel, comprising:
providing a detection device;
holding the liquid crystal panel vertically; and
measuring the cell gap of the liquid crystal panel with the detection device.

2. The method as claimed in claim 1, wherein the liquid crystal panel is a transmissive liquid crystal panel.

3. The method as claimed in claim 1, wherein the liquid crystal panel is a reflective liquid crystal panel.

4. The method as claimed in claim 1, wherein the liquid crystal panel is a reflective-transmissive liquid crystal panel.

5. The method as claimed in claim 1, further comprising:
heating the liquid crystal panel to a detection temperature between 50° C. to 70° C.

6. The method as claimed in claim 5, wherein the detection temperature is about 60° C.

7. The method as claimed in claim 1, wherein the detection device continuously monitors the liquid crystal panel for 3 hours.

8. The method as claimed in claim 1, wherein the detection device detects a lower area of the liquid crystal panel.

9. The method as claimed in claim 8, wherein the detection device detects a lower corner area of the liquid crystal panel.

10. The method as claimed in claim 8, wherein the detection device detects a lower edge area of the liquid crystal panel.

11. The method as claimed in claim 1, wherein the detection device is an optical detection device.

12. A detection apparatus for measuring a cell gap of a liquid crystal panel, comprising:
a holder, holding the liquid crystal panel vertically; and
a detection device, measuring the cell gap of the liquid crystal panel;
wherein the holder supports the liquid crystal panel.

13. The detection apparatus as claimed in claim 12, wherein the holder comprises at least one vacuum element to draw the liquid crystal panel.

14. The detection apparatus as claimed in claim 12, wherein the holder comprises a pivot element pivoting the holder between a vertical orientation and a horizontal orientation.

15. The detection apparatus as claimed in claim 14, wherein the holder holds the liquid crystal panel in the horizontal orientation and rotates the liquid crystal panel to the vertical orientation.

16. The detection apparatus as claimed in claim 15, wherein the holder rotates to the horizontal orientation and releases the liquid crystal panel after detection.

17. The detection apparatus as claimed in claim 14, further comprising a positioning element detecting the position of the holder to ensure that the holder is in the vertical orientation.

18. The detection apparatus as claimed in claim 12, further comprising a heating device heating the liquid crystal panel.

19. The detection apparatus as claimed in claim 12, further comprising a controller coupled to the detection device to control a sensitivity of the detection device.

20. The detection apparatus as claimed in claim 12, further comprising a controller coupled to the detection device to output a measurement result.

21. A method for measuring a cell gap of a liquid crystal panel in a high temperature ageing test, comprising:
providing a detection device;
holding the liquid crystal panel vertically;
heating the liquid crystal panel to a detection temperature; and
measuring the cell gap of the liquid crystal panel with the detection device.

22. The method as claimed in claim 21, wherein the liquid crystal panel is a transmissive liquid crystal panel.

23. The method as claimed in claim 21, wherein the liquid crystal panel is a reflective liquid crystal panel.

24. The method as claimed in claim 21, wherein the liquid crystal panel is a reflective-transmissive liquid crystal panel.

25. The method as claimed in claim 21, wherein the detection temperature is between 50° C. to 70° C.

26. The method as claimed in claim 25, wherein the detection temperature is a predetermined temperature of the high temperature ageing test.

27. The method as claimed in claim 21, wherein the detection device continuously monitors the liquid crystal panel for 3 hours.

28. The method as claimed in claim 21, wherein the detection device detects a lower area of the liquid crystal panel.

29. The method as claimed in claim 28, wherein the detection device detects a lower corner area of the liquid crystal panel.

30. The method as claimed in claim 28, wherein the detection device detects a lower edge area of the liquid crystal panel.

31. The method as claimed in claim 21, wherein the detection device is an optical detection device.
